(19) United States
(12) Patent Application Publication
(10) Pub. No.: US 2025/0386731 A1
(43) Pub. Date: Dec. 18, 2025

(54) THERMOELECTRIC MATERIAL, THERMOELECTRIC ELEMENT, THERMOELECTRIC MODULE, DEVICE, AND METHOD FOR MANUFACTURING THERMOELECTRIC MATERIAL

(71) Applicants: KELK Ltd., Hiratsuka-shi (JP); NATIONAL INSTITUTE OF ADVANCED INDUSTRIAL SCIENCE AND TECHNOLOGY, Tokyo (JP); JAPAN ADVANCED INSTITUTE OF SCIENCE AND TECHNOLOGY, Nomi-shi (JP)

(72) Inventors: Shinichi Fujimoto, Hiratsuka-shi (JP); Michihiro Ohta, Tsukuba-shi (JP); Kazuki Imasato, Tsukuba-shi (JP); Mikio Koyano, Nomi-shi (JP); Masanobu Miyata, Nomi-shi (JP)

(73) Assignees: KELK Ltd., Hiratsuka-shi (JP); NATIONAL INSTITUTE OF ADVANCED INDUSTRIAL SCIENCE AND TECHNOLOGY, Tokyo (JP); JAPAN ADVANCED INSTITUTE OF SCIENCE AND TECHNOLOGY, Nomi-shi (JP)

(21) Appl. No.: 18/879,102

(22) PCT Filed: Jun. 29, 2023
(86) PCT No.: PCT/JP2023/024251

§ 371 Date: Dec. 26, 2024

(30) Foreign Application Priority Data
Jun. 29, 2022 (JP) 2022-104443

(51) Int. Cl. H10N 10/852; H10N 10/01; H10N 10/855

(52) U.S. Cl. CPC H10N 10/852; H10N 10/01; H10N 10/855

(57) ABSTRACT

This thermoelectric material has a matrix in which a chemical formula is represented by A₂B₃, A in the chemical formula is one or more elements selected from the group consisting of Bi and Sb, and B in the chemical formula is one or more elements selected from the group consisting of Te, Se and S, in at least one of crystal grains of the matrix and crystal grain boundaries of the matrix, oxide particles containing one or more elements selected from a group C consisting of Zn, Nb and Al and telluride particles containing one or more elements selected from the group C are precipitated.

### TECHNICAL FIELD

The present invention relates to a thermoelectric material, a thermoelectric element, a thermoelectric module, a device and a method for manufacturing a thermoelectric material.

Priority is claimed on Japanese Patent Application No. 2022-104443, filed in Japan on Jun. 29, 2022, the content of which is incorporated herein by reference.

### BACKGROUND ART

Conventionally, as a thermoelectric material, a material called a Bi—Te-based thermoelectric material is mainly in use. The composition formula of the Bi—Te-based thermoelectric material is represented by Bi₂Te₃, and materials having a composition in which part or all of Bi sites in the thermoelectric material are substituted with Sb and part or all of Te sites are substituted with Se or S are in use.

A-figure of merit Z that indicates the performance of a thermoelectric material is represented by Z=α²σ/κ. Here, α represents the Seebeck coefficient, σ represents the electrical conductivity, and κ represents the thermal conductivity. In order to improve the figure of merit Z of a thermoelectric material, reduction of the lattice thermal conductivity or improvement in the carrier mobility has been thus far tried, but both the thermal conductivity and the Seebeck coefficient are a function of carrier concentration and thus have a trade-off relationship in many cases.

In Patent Document 1, as a Bi—Te-based thermoelectric material, a thermoelectric material to which Ti, V, Cr, Mn, Fe, Co, Ni, Cu, Zn, Zr, Nb, Mo, Y, La, Ce, Nd, Sm and Mm (misch metal) are added to accelerate the amorphization of crystals and to reduce the thermal conductivity has been proposed.

Non-Patent Document 1 describes that Zn is added to a p-type Bi—Te-based thermoelectric material and segregated ZnTe contributes to reduction of the thermal conductivity.

In Patent Document 2, a thermoelectric material including a plurality of zinc oxide nanoparticles in a plurality of bismuth antimony telluride matrix particles of a p-type Bi—Te-based thermoelectric material and zinc antimony modified grain boundaries between the plurality of bismuth antimony telluride matrix particles has been proposed.

### CITATION LIST

### Patent Documents

Patent Document 1: Japanese Patent No. 3092463
Patent Document 2: Japanese Unexamined Patent Application, First Publication No. 2014-022731

### Non-Patent Document

Non-Patent Document 1: Rigui Deng, et. al., Energy Environ. Sci., 2018, 11, 1520

### SUMMARY OF INVENTION

### Technical Problem

In the thermoelectric material of Patent Document 1, the figure of merit is improved by accelerating amorphization. However, ordinarily, amorphization or crystal refinement in Bi—Te-based thermoelectric materials brings about a decrease in carrier mobility as well as reduction of thermal conductivity, which makes it difficult to improve the figure of merit.

Non-Patent Document 1 discloses an instance where an effect of thermal conductivity reduction by segregated ZnTe is exhibited; however, in the case of a Zn-added sample where oxidation is unlikely to occur, an effect of thermal conductivity reduction by the precipitation of ZnTe can be seen; however, at the same time, there is a problem in that the carrier mobility decreases and a figure of merit improvement effect is not sufficient.

In Patent Document 2, mobility is improved by zinc antimony modified grain boundaries. Zinc antimony modified grain boundaries are formed in the case of a manufacturing method where a solution is used such as wet chemical synthesis. Zinc antimony modified grain boundaries are not formed in a melting method, which is used for the mass production of an ordinary thermoelectric material and are thus not suitable for mass production. In addition, zinc antimony modified grain boundaries are not suitable for industrial products due to the weak brittleness or easily oxidizable property of zinc antimony. In Patent Document 2, upon synthesis, since Zn is used in a zinc oxide form from the beginning, there is no oxide reduction effect by Zn, and an Sb oxide is contained in a quantity large enough to be easily observed by the X-ray diffraction method (XRD). This Sb oxide also act as a characteristics deterioration factor and is thus preferably not contained.

The present invention is an invention made in consideration of the above-described circumstances, and an objective of the present invention is to provide a thermoelectric material having an excellent figure of merit, a thermoelectric element, a thermoelectric module, a device and a method for manufacturing a thermoelectric material.

### Solution to Problem

A thermoelectric material according to one aspect of the present invention has a matrix in which a chemical formula is represented by A₂B₃, A in the chemical formula is one or more elements selected from the group consisting of Bi and Sb, and B in the chemical formula is one or more elements selected from the group consisting of Te, Se and S, in at least one of crystal grains of the matrix and crystal grain boundaries of the matrix, oxide particles containing one or more elements selected from a group C consisting of Zn, Nb and Al and telluride particles containing one or more elements selected from the group C are precipitated, major axes of the oxide particles are 1 nm to 1000 nm, minor axes of the oxide particles are 1 nm to 500 nm, major axes of the telluride particles are 0.4 μm to 40 μm, and minor axes of the telluride particles are 0.4 μm to 20 μm.

### Advantageous Effects of Invention

According to the above-described aspect of the present invention, it is possible to provide a thermoelectric material having an excellent figure of merit, a thermoelectric element, a thermoelectric module, a device and a method for manufacturing a thermoelectric material.

### BRIEF DESCRIPTION OF DRAWINGS

FIG. 1 is a flowchart of a method for manufacturing a thermoelectric material according to an embodiment.

FIG. 2 is a figure for describing cutting positions of measurement samples.

FIG. 3 is a figure showing temperature dependence of Seebeck coefficients α of p-type thermoelectric materials produced by pulverizing ingots in the atmosphere.

FIG. 4 is a figure showing temperature dependence of electric resistivity ρ of the p-type thermoelectric materials produced by pulverizing the ingots in the atmosphere.

FIG. 5 is a figure showing temperature dependence of thermal conductivities κ of the p-type thermoelectric materials produced by pulverizing the ingots in the atmosphere.

FIG. 6 is a figure showing temperature dependence of figures of merit Z of the p-type thermoelectric materials produced by pulverizing the ingots in the atmosphere.

FIG. 7 is a figure showing temperature dependence of weighted mobility μ_{w} of the p-type thermoelectric materials produced by pulverizing the ingots in the atmosphere.

FIG. 8 is a figure showing temperature dependence of lattice thermal conductivity κₗₐₜ of the p-type thermoelectric materials produced by pulverizing the ingots in the atmosphere.

FIG. 9 is a figure showing temperature dependence of figures of merit Z of the p-type thermoelectric materials produced by pulverizing the ingots in the atmosphere and p-type thermoelectric materials in a case where ingots have been powdered in an inert gas atmosphere.

FIG. 10 is a figure showing temperature dependence of quality factors B of the p-type thermoelectric material produced by pulverizing the ingot in the atmosphere and the p-type thermoelectric material produced by pulverizing the ingot in the inert gas atmosphere (in a glove box).

FIG. 11 is a figure showing a distribution of major axes of zinc telluride particles in the p-type thermoelectric material produced by pulverizing the ingot in the atmosphere.

FIG. 12 is a figure showing a distribution of minor axes of the zinc telluride particles in the p-type thermoelectric material produced by pulverizing the ingot in the atmosphere.

FIG. 13 is a figure showing a distribution of major axes of zinc oxide particles in the p-type thermoelectric material produced by pulverizing the ingot in the atmosphere.

FIG. 14 is a figure showing a distribution of minor axes of the zinc oxide particles in the p-type thermoelectric material produced by pulverizing the ingot in the atmosphere.

FIG. 15 is a figure showing results of Sb and O element mappings of a thermoelectric material without Zn.

FIG. 16 is a figure showing temperature dependence of thermal conductivity of a p-type thermoelectric material obtained by adding zinc oxide to a raw material and a p-type thermoelectric material obtained by adding pure zinc to a raw material.

FIG. 17 is a figure showing ZnTe amount dependence of a dimensionless figure of merit ZT of an n-type thermoelectric material 2 at near room temperature (325 K).

FIG. 18 is a figure showing element mapping results of the n-type thermoelectric material 2.

FIG. 19 is a figure showing temperature dependence of lattice thermal conductivities κₗₐₜ of Bi₂Se_{0.3}Te_{2.7}, an n-type thermoelectric material 3 and an n-type thermoelectric material 4.

FIG. 20 is a figure showing a relationship between Quality factor B and the Al amount.

FIG. 21 is a figure showing temperature dependence of dimensionless figures of merit ZT of Bi_{0.45}Sb_{1.55}Te₃, a p-type thermoelectric material 2 and a p-type thermoelectric material 3.

### DESCRIPTION OF EMBODIMENTS

### <Thermoelectric Material>

A thermoelectric material according to an embodiment of the present invention has a matrix in which the chemical formula is represented by A₂B₃, A in the chemical formula is one or more elements selected from the group consisting of Bi and Sb, and B in the chemical formula is one or more elements selected from the group consisting of Te, Se and S, in at least one of crystal grains of the matrix and crystal grain boundaries of the matrix, oxide particles containing one or more elements selected from a group C consisting of Zn, Nb and Al (hereinafter, referred to as the oxide particles containing an element of the group C) and telluride particles containing one or more elements selected from the group C (hereinafter, referred to as the telluride particles containing an element of the group C) are precipitated, the major axes of the oxide particles containing an element of the group Care 1 nm to 1000 nm, the minor axes of the oxide particles containing an element of the group C are 1 nm to 500 nm, the major axes of the telluride particles containing an element of the group C are 0.4 μm to 40 μm, and the minor axes of the telluride particles containing an element of the group Care 0.4 μm to 20 μm. The thermoelectric material according to the present embodiment can be used as both an n-type semiconductor and a p-type semiconductor. In the present specification, numerical ranges expressed using “to” include numerical values before and after “to” as the lower limit value and the upper limit value. Numerical values expressed with “more than” and “less than” are not included in numerical ranges. Hereinafter, each element will be described.

### <Matrix>

In the thermoelectric material according to the present embodiment, the chemical formula is represented by A₂B₃, A in the chemical formula is one or more elements selected from the group consisting of Bi and Sb (hereinafter, referred to as the element of the group A in some cases), and B in the chemical formula is one or more elements selected from the group consisting of Te, Se and S (hereinafter, referred to as the element of the group B in some cases). The ratio between the total number of atoms in the element of the group A and the total number of atoms in the element of the group B (the element of the group A: the element of the group B) is 2:3. Examples of the matrix include Bi₂Te₃, Sb₂Te₃, Bi₂Se₃, Sb₂Se₃, Bi₂S₃, Sb₂S₃, Bi_{0.46}Sb_{1.54}Te₃, (Bi_{0.225}Sb_{0.775})₂Te₃ and the like. In the matrix, Te is preferably contained.

In a case where the thermoelectric material according to the embodiment is used as an n-type semiconductor, the proportion of Se and S in the element of the group B is preferably increased in the matrix. Specifically, it is preferable to set the ratio in the number of atoms of Se and S to Te ((Se+S)/(Te+Se+S)) in the matrix to 0 to 0.33.

In a case where the thermoelectric material according to the embodiment is used as a p-type semiconductor, the proportion of Sb in the element of the group A is preferably increased in the matrix. Specifically, it is preferable to set the ratio in the number of atoms of Bi to Sb (Bi/(Sb+Bi)) in the matrix to 0 to 0.30.

In a case where the thermoelectric material according to the embodiment is used as an n-type semiconductor, a halogen element such as Cl. Se or I is preferably contained. The content of the halogen element is preferably set to 0.030 at % to 0.20 at % relative to the entire matrix. The content of the halogen element is more preferably 0.050 at % to 0.12 at %.

In a case where the thermoelectric material according to the embodiment is used as a p-type semiconductor, a Group 14 element such as Ge, Sn or Pb is preferably contained in the matrix. The content of the Group 14 element is preferably set to 0 at % to 0.20 at % relative to the entire matrix. The content of the Group 14 element is more preferably 0 at % to 0.15 at %. The at % of each element can be analyzed with, for example, an inductively coupled plasma mass spectrometer (ICP-MS).

The matrix of the thermoelectric material according to the embodiment is preferably polycrystalline. It is more preferable that no amorphous phase-derived halo patterns are shown in the X-ray diffraction method.

### <Oxide Particles Containing Element of Group C>

In the thermoelectric material according to the embodiment, oxide particles containing one or more elements of group C selected from the group consisting of Zn, Nb and Al are precipitated in at least one of crystal grains of the matrix and crystal grain boundaries of the matrix. In the thermoelectric material in the embodiment, the oxide particles containing an element of group C preferably contain at least Zn. In addition, in the thermoelectric material in the embodiment, the oxide particles containing an element of group C preferably contain at least Nb. In the thermoelectric material in the embodiment, the oxide particles containing an element of group C preferably contain at least Al. In the thermoelectric material in the embodiment, the oxide particles containing an element of group C particularly preferably contain at least Zn. The oxide particles containing an element of group C are, for example, zinc oxide (ZnO) particles. In the thermoelectric material according to the embodiment, it is preferable that the number of oxide particles containing an element of group C is larger than the number of telluride particles containing an element of group C. It is preferable that the number of oxide particles containing an element of group C is larger than the number of particles of a pure element of group C.

The major axes of the oxide particles containing an element of group C are 1 nm to 1000 nm. The major axes of the oxide particles containing an element of group C are preferably 20 nm to 480 nm. The major axes of the oxide particles containing an element of group C are more preferably 20 nm to 350 nm. 75% or more of the oxide particles containing an element of group C may satisfy this numerical range of the major axes. It is more preferable that 80% or more of the oxide particles containing an element of group C satisfy this numerical range of the major axes. It is still more preferable that 90% or more of the oxide particles containing an element of group C satisfy this numerical range of the major axes.

The minor axes of the oxide particles containing an element of group Care 1 nm to 500 nm. The minor axes of the oxide particles containing an element of group C are preferably 10 nm to 260 nm. The minor axes of the oxide particles containing an element of group C are more preferably 10 nm to 190 nm. 75% or more of the oxide particles containing an element of group C may satisfy this numerical range of the minor axes. It is more preferable that 80% or more of the oxide particles containing an element of group C satisfy this numerical range of the minor axes. It is still more preferable that 90% or more of the oxide particles containing an element of group C satisfy this numerical range of the minor axes.

### <Telluride Particles Containing Element of Group C>

In the thermoelectric material according to the embodiment, telluride particles containing one or more elements of group C selected from the group consisting of Zn, Nb and Al are precipitated in at least one of crystal grains of the matrix and crystal grain boundaries of the matrix. The element of group C is an element that does not easily substitute an A or B site in A₂B₃, enters between the crystal lattices of A₂B₃, and does not significantly change the carrier concentration and is an element having a higher ionization tendency than the element of the group A and the element of the group B. The element of group C is an element that has a higher ionization tendency than the element of the group A and the element of the group B and thus functions as a getter material that absorbs oxygen. In the thermoelectric material in the embodiment, the telluride particles containing an element of group C preferably contain at least Zn. In addition, in the thermoelectric material in the embodiment, the telluride particles containing an element of group C preferably contain at least Nb. In the thermoelectric material in the embodiment, the telluride particles containing an element of group C preferably contain at least Al. In the thermoelectric material in the embodiment, the telluride particles containing an element of group C particularly preferably contain at least Zn. The telluride particles are, for example, zinc telluride (ZnTe) particles. At least one of the oxide particles containing an element of group C and the telluride particles containing an element of group C may contain at least Zn. At least one of the oxide particles containing an element of group C and the telluride particles containing an element of group C may contain at least Nb. At least one of the oxide particles containing an element of group C and the telluride particles containing an element of group C may contain at least Al.

The major axes of the telluride particles containing an element of group C are 0.4 μm to 40 μm. The major axes of the telluride particles containing an element of group C are preferably 0.6 μm to 21 μm. The major axes of the telluride particles containing an element of group C are more preferably 0.6 μm to 15 μm. 75% or more of the telluride particles containing an element of group C may satisfy this numerical range of the major axes. It is more preferable that 80% or more of the telluride particles containing an element of group C satisfy this numerical range of the major axes. It is still more preferable that 90% or more of the telluride particles containing an element of group C satisfy this numerical range of the major axes.

The minor axes of the telluride particles containing an element of group C are 0.4 μm to 20 μm. The minor axes of the telluride particles containing an element of group C are preferably 0.4 μm to 10.5 μm. The minor axes of the telluride particles containing an element of group C are more preferably 0.4 μm to 7.5 μm. 75% or more of the telluride particles containing an element of group C need to satisfy this numerical range of the minor axes. It is more preferable that 80% or more of the telluride particles containing an element of group C satisfy this numerical range of the minor axes. It is still more preferable that 90% or more of the telluride particles containing an element of group C satisfy this numerical range of the minor axes.

### <Method for Measuring Major Axes and Minor Axes of Oxide Particles Containing Element of Group C and Telluride Particles Containing Element of Group C>

The major axes and minor axes of the oxide particles containing an element of group C and the telluride particles containing an element of group C can be measured by, for example, the following method. The thermoelectric material is processed by, for example, ion milling, focused ion beam (FIB) or the like, thereby obtaining a sample for cross-sectional observation. Cross-sectional observation is performed on the obtained sample for cross-sectional observation with a transmission electron microscope (TEM) or a scanning electron microscope (SEM), thereby obtaining a cross-sectional image. In the cross-sectional observation, element mapping is performed using, for example, an energy-dispersive X-ray spectrometer (EDS) attached to TEM or the like. In the element mapping, particles from which the element of group C and oxygen are detected are regarded as the oxide particles containing an element of group C, and particles from which the element of group C and Te are detected are regarded as the telluride particles containing an element of group C. Particles from which only the element of group C is detected are regarded as the particles of a pure element of group C. Image processing is performed on an obtained element mapping image using image analysis software such as ImageJ Fiji by setting a threshold value so that the outlines of the oxide particles and the telluride particles become clear (for example, 5.94% of a concentration distribution histogram on the background side upon binarization is removed or the like). An elliptic approximation treatment is performed on the obtained oxide particles and telluride particles, whereby it is possible to obtain the major axes and minor axes of the oxide particles containing an element of group C and the telluride particles containing an element of group C. In a case where particles to be measured are spherical, the particles are treated by performing an elliptic treatment in the same manner. Regarding the oxide particles containing an element of group C, eight visual fields are observed (for example, measurement visual field: 3.3 μm×3.3 μm), regarding the telluride particles containing an element of group C, four visual fields are observed (for example, measurement visual field: 414 μm×285 μm), and the ranges of the major axes and the minor axes are evaluated from the major axes and the minor axes of the oxide particles containing an element of group C and the major axes and the minor axes of the telluride particles containing an element of group C obtained from each mapping image.

### <Zn Content>

The Zn content of the thermoelectric material according to the embodiment is preferably 0.40 to 2.3 at % relative to the entire thermoelectric material. The Zn content is more preferably 0.40 to 1.2 at %. The Zn content is still more preferably 0.79 to 1.2 at %. The content of Zn in the thermoelectric material according to the embodiment can be measured with, for example, an inductively coupled plasma mass spectrometer (ICP-MS). The numerical value of the content was round off to two digits.

### <Al Content>

The Al content according to the embodiment is preferably 1.99 to 3.97 at % relative to the entire thermoelectric material. The content of Zn in the thermoelectric material according to the embodiment can be measured with, for example, an inductively coupled plasma mass spectrometer (ICP-MS). The numerical value of the content was round off to three digits.

### <Sb Oxide>

In the thermoelectric material according to the embodiment, the maximum value of the number densities of Sb oxide particles is preferably 31.2 particles/μm² or less. The maximum value of the number densities of the Sb oxide particles is more preferably 12.4 particles/μm² or less. The maximum value of the number densities of Sb oxide particles is still more preferably 1.6 particles/μm² or less. Since the Sb oxide is preferably as few as possible, the lower limit of the number densities of Sb oxide particles is 0 particles/μm². The Sb oxide is, for example, Sb₂O₃.

### <Bi Oxide>

In the thermoelectric material according to the embodiment, the maximum value of the number densities of Bi oxide particles is preferably 31.2 particles/μm² or less. The maximum value of the number densities of the Bi oxide particles is more preferably 12.4 particles/μm² or less. The maximum value of the number densities of Bi oxide particles is still more preferably 1.6 particles/μm² or less. Since the Bi oxide is preferably as few as possible, the lower limit of the maximum value of the number densities of Bi oxide particles is 0 particles/μm². The Bi oxide is, for example, Bi₂O₃.

### <Method for Measuring Number Densities of Sb Oxide Particles and Bi Oxide Particles>

The number densities of the Sb oxide particles and the Bi oxide particles can be measured by, for example, the following method. The thermoelectric material is processed by, for example, focused ion beam (FIB) or the like, thereby obtaining a sample for cross-sectional observation. The obtained sample for cross-sectional observation is observed with a transmission electron microscope (TEM) or the like, thereby obtaining a cross-sectional image. In the cross-sectional observation, element mapping is performed using, for example, an energy-dispersive X-ray spectrometer attached to TEM or the like, particles from which Sb and oxygen are detected are regarded as the Sb oxide particles, and particles from which Bi and oxygen are detected are regarded as the Bi oxide particles. Eight visual fields are observed (for example, measurement visual field: 3.3 μm×3.3 μm), and the number density of the Sb oxide particles and the number density of the Bi oxide particles are calculated from the number of the Sb oxide particles and the number of the Bi oxide particles obtained from the cross-sectional image and the area of the measurement visual field. The maximum value of the number densities of the Sb oxide particles in the individual visual fields obtained by the measurement at eight visual fields is regarded as the maximum value of the number densities of the Sb oxide particles. The maximum value of the number densities of the Bi oxide particles in the individual visual fields obtained by the measurement at eight visual fields is regarded as the maximum value of the number densities of the Bi oxide particles.

### <Oxygen Concentration>

The oxygen concentration of the thermoelectric material according to the embodiment is preferably 100 ppm or more. The oxygen concentration is more preferably 400 ppm or more. The oxygen concentration is still more preferably 1000 ppm or more. The oxygen concentration of the thermoelectric material can be measured by, for example, an inert gas fusion-non-dispersive infrared absorption method (NDIR).

Hitherto, the thermoelectric material according to the embodiment has been described. The thermoelectric material according to the embodiment can be used for thermoelectric elements. In addition, the thermoelectric element can be used in thermoelectric modules. In addition, the thermoelectric module can be used in devices such as precision temperature control devices or power generation apparatuses.

### Effect

In the thermoelectric material according to the embodiment, since the oxide particles containing an element of the group C (major axes: 1 nm to 1000 nm, minor axes: 1 nm to 500 nm) are precipitated in at least one of crystal grains of the matrix and crystal grain boundaries of the matrix, it is possible to reduce the lattice thermal conductivity without decreasing the carrier mobility. This makes it possible to improve the figure of merit Z of the thermoelectric material according to the embodiment.

In the thermoelectric material according to the embodiment, since the telluride particles containing an element of the group C (major axes: 0.4 μm to 40 μm, minor axes: 0.4 μm to 20 μm) are precipitated in at least one of crystal grains of the matrix and crystal grain boundaries of the matrix, it is possible to reduce the lattice thermal conductivity. This makes it possible to improve the figure of merit Z of the thermoelectric material according to the embodiment.

In the thermoelectric material according to the embodiment, the number of the oxide particles containing an element of the group C is made to be larger than the telluride particles containing an element of the group C, whereby it is possible to further improve the figure of merit Z of the thermoelectric material according to the embodiment.

The number density of the number densities of the Sb oxide particles and the Bi oxide particles according to the embodiment is set to 31.2 particles/μm² or less, whereby it is possible to further improve the carrier mobility of the thermoelectric material according to the embodiment.

When the oxygen concentration of the thermoelectric material according to the embodiment is 1000 ppm or more, an appropriate number of oxide particles containing an element of the group C are formed, and it is possible to further improve the figure of merit Z.

### <Method for Manufacturing Thermoelectric Material>

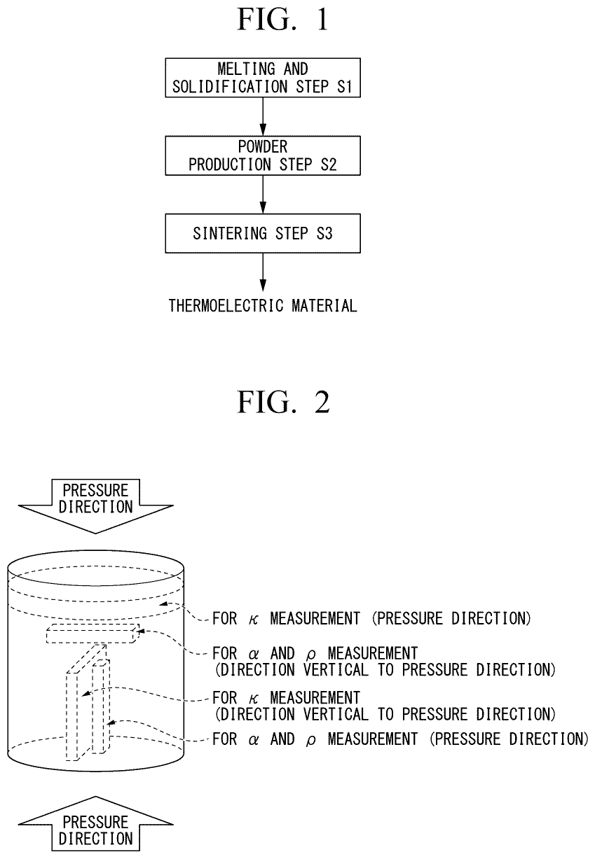

Next, a method for manufacturing a thermoelectric material according to the embodiment will be described. The manufacturing method to be described below is an example of a method for manufacturing the thermoelectric material according to the embodiment, and the present invention is not limited to the following manufacturing method. FIG. 1 is a flowchart of the method for manufacturing a thermoelectric material according to the embodiment. The method for manufacturing a thermoelectric material according to the embodiment includes a melting and solidification step S1 of melting and solidifying a raw material containing an element of the group A that is at least one selected from the group consisting of Bi and Sb an element of the group B that is at least one selected from the group consisting of Te, Se and S and an element that is at least one selected from the group C consisting of Zn, Nb and Al to obtain a solidified product, a powder production step S2 of obtaining a powder from the solidified product and a sintering step S3 of sintering the powder. In the melting and solidification step S1, at least some of the one or more elements selected from the group C in the raw material are present as a pure element. Hereinafter, each step will be described.

### <Melting and Solidification Step>

In the melting and solidification step S1, a raw material containing at least one element selected from the group A consisting of Bi and Sb, at least one element selected from the group B consisting of Te, Se and S and at least one element selected from the group C consisting of Zn, Nb and Al is melted and solidified.

### <Raw Material>

The raw material contains at least one element selected from the group A consisting of Bi and Sb, at least one element selected from the group B consisting of Te. Se and S and at least one element selected from the group C consisting of Zn, Nb and Al. For the raw material, the atom proportion of each element may be determined so that, for example, y at % of a telluride containing an element of the group C and the remainder becomes a matrix represented by a composition formula A₂B₃. Here, y in y at % means the atom concentration of the telluride containing an element of the group C relative to all atoms in the raw material. Here, A in the composition formula means at least one element selected from the group consisting of Bi and Sb. In addition, B in the composition formula means at least one element selected from the group consisting of Te. Se and S. The telluride containing an element of the group C is ZnTe, Al₂Te₃, NbTe₂, Nb₃Te₄, NbTe₄ or the like. The telluride containing an element of the group C does not need to be contained as a telluride, and the element of the group C and Te may be each contained as a pure element in the raw material. In the present embodiment, at least some containing the element of the group C in the raw material may be present as a pure element. The element of the group C is preferably present in the raw material as a pure element. It is preferable that individual elements are present in a uniformly-mixed state in the raw material. In addition, in the raw material, a halogen element and a Group 14 element, which have been exemplified above, may be contained.

### <Heating Temperature>

In the melting and solidification step S1, the raw material is heated at a heating temperature of the melting point of the raw material or higher and 1000° C. or lower in a vacuum or in an inert gas. It is more preferable that the raw material is heated within a range of 650° C. to 850° C. The heating temperature at this time is, for example, the set temperature of a heating furnace. When the raw material is heated within a range of 650° C. to 850° C., each element in the raw material can be melted.

### <Heating Time>

The raw material is heated at the heating temperature for a certain period of time. The heating time is not particularly limited as long as the raw material is completely fused. For example, the heating time is one hour to 60 hours.

### <Temperature Rising Rate>

In the melting and solidification step S1, the average temperature rise rate at the time of raising the temperature from room temperature (for example, 20° C. to 30° C.) to the heating temperature is preferably, for example, 1° C./minute to 20° C./minute. In order to suppress the oxidation of the raw material, it is preferable to heat the raw material in a vacuum or in an inert gas.

### <Temperature Dropping Rate>

In the melting and solidification step S1, after the raw material is heated for a certain period of time, the temperature drops from the heating temperature to room temperature, thereby obtaining a solidified product. The average temperature drop rate at the time of dropping the temperature from the heating temperature to room temperature is preferably, for example, 0.1° C./minute to 20° C./minute.

### <Powder Production Step>

In the powder production step S2, a powder is obtained from the solidified product obtained in the melting and solidification step. In some cases, voids remain in the solidified product, and there are cases where an element segregates. Therefore, the solidified product is made into a powder. At this time, it is preferable to pulverize the solidified product in the atmosphere or to expose the produced powder in the atmosphere.

A method for producing a powder is not particularly limited. Examples of the method for producing a powder include pulverization with a mortar, a blender mill, a ball mill or the like, an atomization method, a melt-spun method and the like.

### <Sintering Step>

In the sintering step S3, the powder obtained in the powder production step S2 is sintered, thereby obtaining a thermoelectric material. The sintering method is not particularly limited. Examples of the sintering method include hot-pressing sintering or pulsed electric current sintering (PECS). In pulsed electric current sintering, it is possible to rapidly raise the temperature up to the target.

The sintering temperature, the sintering pressure and the sintering time are not particularly limited as long as an intended thermoelectric material can be obtained. For example, the sintering temperature is preferably 350° C. to 550° C. In addition, the sintering pressure is preferably, for example, 10 MPa to 90 MPa. Additionally, the sintering time is preferably, for example, one minute to 120 minutes.

The atmosphere during sintering is not particularly limited as long as an intended thermoelectric material can be obtained but is preferably a vacuum or an inert gas atmosphere to suppress oxidation during sintering.

### Effect

In the related art, it was common to add a zinc oxide powder in a stage before synthesis. In this case, the grain diameters of the zinc oxide powder do not become equal to or smaller than the original. In addition, zinc oxide has a small specific gravity and a high melting point and thus remains separated in the bottom part of a glass pipe or quartz pipe or agglomerates in a powder form without melting or dispersing in the matrix. For this reason, it was difficult to evenly disperse zinc oxide particles.

On the other hand, in the method for manufacturing a thermoelectric material of the present embodiment, an element of group C such as zinc and Te are added to the raw material so as to be excessive, whereby it is possible to precipitate and disperse zinc oxide nanoparticles. In this case, a telluride containing the element of group C also precipitates and is capable of contributing to the reduction of the thermal conductivity and improving the figure of merit.

In the thermoelectric material according to the embodiment, at least some containing the element of group C in the raw material is present as a pure element, whereby it is possible to make the thermoelectric material function as a getter material that absorbs oxygen. This makes it possible to set the maximum values of the number densities of the Sb oxide particles and the Bi oxide particles to 31.2 particles/μm² or less. Therefore, it is possible to further improve the figure of merit Z of the thermoelectric material.

In the powder production step S2, the solidified product is pulverized in the atmosphere or exposed in the atmosphere, whereby it is possible to actively proceed with oxidation. This makes it possible to obtain an oxygen concentration of 1000 ppm or more in the thermoelectric material. When the oxygen concentration in the thermoelectric material is 1000 ppm or more, an appropriate number of oxide particles containing an element of group C are formed, and it is possible to further improve the figure of merit Z.

Hitherto, the embodiment of the present invention has been described, but the present invention is not limited thereto and can be modified as appropriate within the scope of the technical concept of the invention.

### EXAMPLES

Next, examples of the present invention will be described. Conditions in the examples are examples of conditions adopted to confirm the feasibility and effect of the present invention, and the present invention is not limited to the examples of conditions. The present invention is capable of adopting a variety of conditions as long as the objective of the present invention is achieved without departing from the gist of the present invention.

### Details of Examples

Raw materials containing Bi, Sb, Te, Se, Zn and Al, each as a pure element, according to each composition were sealed in quartz or PYREX (registered trademark) glass pipes and heated, melted at a temperature of 650° C. or higher, which is higher than the melting points of alloys (the melting point of Bi₂Te₃: 588.5° C., the melting point of Sb₂Te₃: 618.5° C.), and 1000° C. or lower, and solidified thereby producing ingots. Prepared compositions at this time are as described below. As a comparative example, an ingot was produced in the same manner from a raw material to which zinc oxide was added instead of pure Zn, and consequently, zinc oxide was not melted and did not uniformly disperse. In addition, as a comparative example. Bi₂Se_{0.3}Te_{2.7} and Bi_{0.45}Sb_{1.55}Te₃ were also produced. The following (BiₓSb₁₋ₓ)₂Te₃+y at % ZnTe means y/100 moles of ZnTe is present relative to one mole of (BiₓSb₁₋ₓ)₂Te₃. Bi_{0.45}Sb_{1.55}Te₃+y at % AlTe means y/100 moles of AlTe is present relative to one mole of Bi_{0.45}Sb_{1.55}Te₃. Bi_{0.45}Sb_{1.55}Te₃+y at % Al₂Te₃ means y/100 moles of Al₂Te₃ is present relative to one mole of Bi_{0.45}Sb_{1.55}Te₃. Similarly, Bi₂(Te_{0.9}Se_{0.1})₃+y at % Zn Te means y/100 moles of ZnTe is present relative to one mole of Bi₂(Te_{0.9}Se_{0.1})₃. The following Bi₂Se_{0.3}Te_{2.7}+y at % ZnTe means y/100 moles of ZnTe is present relative to one mole of Bi₂Se_{0.3}Te_{2.7}. Multiple addition of BiI₃ is performed to adjust the carrier concentration, but there are no direct thermoelectric performance improvement effects. The following Bi₂Se_{0.3}Te_{2.7}+y at % AlTe means y/100 moles of AlTe is present relative to one mole of Bi₂Se_{0.3}Te_{2.7}. The following Bi₂Se_{0.3}Te_{2.7}+y at % Al₂Te₃ means y/100 moles of Al₂Te₃ is present relative to one mole of Bi₂Se_{0.3}Te_{2.7}.
p-Type thermoelectric material 1: (BiₓSb₁₋ₓ)₂Te₃+y at % ZnTe (x=0.2 or 0.225, y=0, 2, 4, 6 or 12)
p-Type thermoelectric material 2: Bi_{0.45}Sb_{1.55}Te₃+y at % AlTe (y=4)
p-Type thermoelectric material 3: Bi_{0.45}Sb_{1.55}Te₃+y at % Al₂Te₃ (y=2)
n-Type thermoelectric material 1: Bi₂(Te_{0.9}Se_{0.1})₃+y at % ZnTe (y=0, 2 or 4)
n-Type thermoelectric material 2: Bi₂Se_{0.3}Te_{2.7}+y at % ZnTe+0.08 wt % of BiI₃ (y=0, 2 or 4)
n-Type thermoelectric material 3: Bi₂Se_{0.3}Te_{2.7}+y at % AlTe (y=2)
n-Type thermoelectric material 4: Bi₂Se_{0.3}Te_{2.7}+y at % Al₂Te₃ (y=0.5)

Next, the ingots were processed into powders in the atmosphere or in an inert gas (in a glove box), and sintered products (thermoelectric materials) were produced in an inert gas using a sintering apparatus. With an assumption of a case where a current and a heat flow flowed in a pressure direction of the sintered product or a vertical direction thereof, samples for measuring the Seebeck coefficient and electric resistance and samples for measuring thermal conductivity were cut out from the sintered product as shown in FIG. 2.

### <Seebeck Coefficient and Electric Resistivity>

For the measurement of the Seebeck coefficients and the electric resistivity, the samples for measuring the Seebeck coefficient and electric resistance were measured with a thermal electric characteristic evaluation system (ZEM-3M8) manufactured by Advance Riko, Inc. within a temperature range of room temperature to 250° C.

### <Measurement of Major Axes and Minor Axes of Oxide Particles of Zinc and Telluride Particles of Zinc>

Each thermoelectric material was processed by Ar ion milling, and a sample for cross-sectional observation was obtained. The obtained sample for cross-sectional observation was observed with TEM or SEM, and element mapping was performed with EDS. Particles from which zinc and oxygen were detected were regarded as oxide particles containing an element of group C (zinc oxide particles), and particles from which zinc and Te were detected were regarded as telluride particles containing an element of group C (zinc telluride particles). Image processing was performed on the obtained element mapping image using image analysis software ImageJ Fiji by setting a threshold value so that the outlines of the oxide particles and the telluride particles became clear (5.94% of a concentration distribution histogram on the background side upon binarization was removed or the like). An elliptic approximation treatment was performed on the obtained oxide particles and telluride particles, whereby it was possible to obtain the major axes and minor axes of the oxide particles containing an element of group C and the telluride particles containing an element of group C. Regarding the oxide particles, eight visual fields were observed (measurement visual field: 3.3 μm×3.3 μm), regarding the telluride particles, four visual fields were observed (measurement visual field: 414 μm×285 μm), and the ranges of the major axes and the minor axes were evaluated from the major axes and the minor axes of the oxide particles containing an element of group C and the major axes and the minor axes of the telluride particles containing an element of group C obtained from each cross-sectional image.

### <Measurement of Number Densities of Sb Oxide Particles and Bi Oxide Particles>

Each thermoelectric material was processed by focused ion beam (FIB), and a sample for cross-sectional observation was obtained. The obtained sample for cross-sectional observation was observed with TEM, and element mapping was performed with EDS. Particles from which Sb and oxygen were detected were regarded as Sb oxide particles, and particles from which Bi and oxygen were detected were regarded as Bi oxide particles. Eight visual fields were observed (measurement visual field: 3.3 μm×3.3 μm), and the number density of the Sb oxide particles in each visual field was calculated from the number of the Sb oxide particles obtained from each cross-sectional image and the area of the measurement visual field. Among the obtained number densities, the maximum value was regarded as the maximum value of the number densities.

### <Thermal Conductivity>

The thermal conductivity was measured within a temperature range of room temperature to 250° C. with a laser flash apparatus (LFA 467 HyperFlash) manufactured by Netsch.

### <Oxygen Concentration>

The oxygen concentrations of the thermoelectric materials produced above were measured using an oxygen/nitrogen analyzer EMGA-920 manufactured by HORIBA.

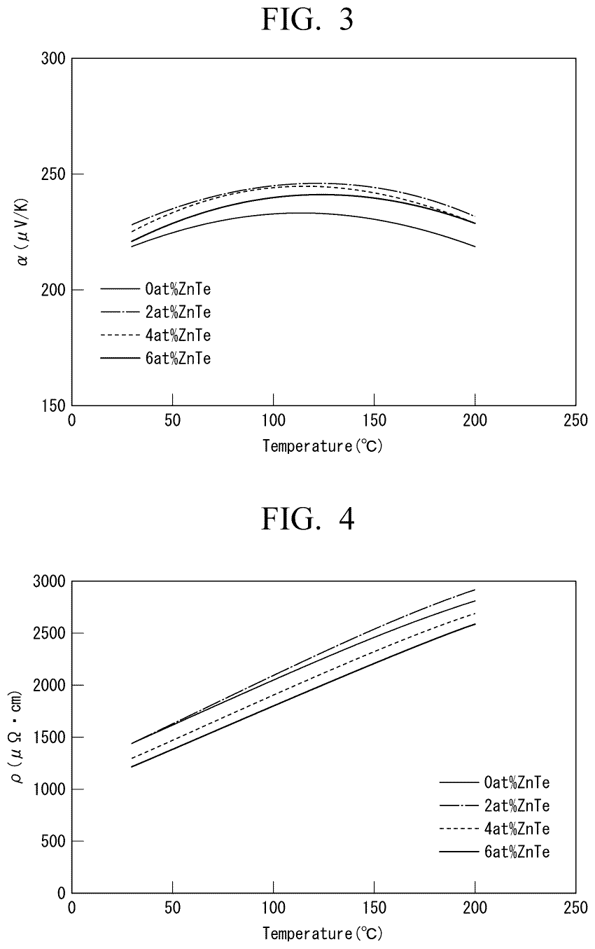

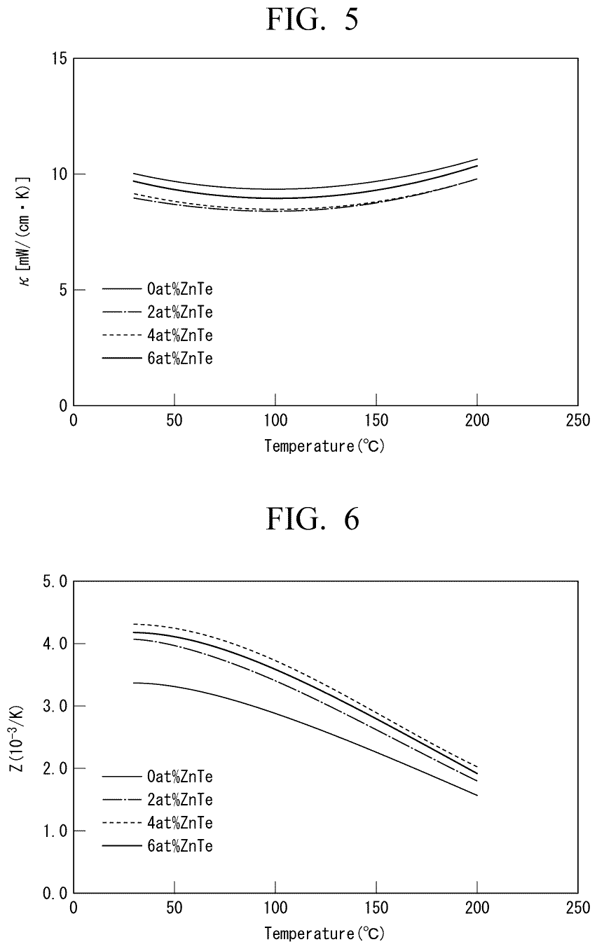

FIG. 3 shows the temperature dependence of the Seebeck coefficients α of the p-type thermoelectric materials produced by powdering ingots in the atmosphere. The horizontal axis of FIG. 3 indicates the temperature (° C.), and the vertical axis of FIG. 3 indicates the Seebeck coefficient α (μV/κ). FIG. 4 shows the temperature dependence of the electric resistivity ρ of the p-type thermoelectric materials produced by powdering the ingots in the atmosphere. The horizontal axis of FIG. 4 indicates the temperature (° C.), and the vertical axis of FIG. 4 indicates the electric resistivity ρ (μΩ·cm). FIG. 5 shows the temperature dependence of the thermal conductivity κ of the p-type thermoelectric materials produced by powdering the ingots in the atmosphere. The horizontal axis of FIG. 5 indicates the temperature (° C.), and the vertical axis of FIG. 5 indicates the thermal conductivity κ (mW/(cm·K)). FIG. 6 shows the temperature dependence of the figures of merit Z of the p-type thermoelectric materials produced by powdering the ingots in the atmosphere. The horizontal axis of FIG. 6 indicates the temperature (° C.), and the vertical axis of FIG. 6 indicates the figure of merit Z (10⁻³/κ).

The results in FIG. 3 to FIG. 6 are results in cases where the amounts of Zn and Te added (0 to 12 at %) were changed so that Zn and Te became excessive in a ratio of 1:1 relative to the chemical stoichiometric composition of (Bi_{0.225}Sb_{0.775})₂Te₃ in terms of the prepared value. Specifically, (Bi_{0.225}Sb_{0.775})₂Te₃+y at % of ZnTe indicates that ZnTe is y/100 moles (y: 0 to 12) relative to one mole of (Bi_{0.225}Sb_{0.775x})₂Te₃. For example, at the time of 2 at % of ZnTe, the Zn content becomes 0.40 at % relative to the entire thermoelectric material. In the case of 4 at % of ZnTe, the Zn content becomes 0.79 at % relative to the entire thermoelectric material. Similarly, in the case of 6 at % of ZnTe, the Zn content is 1.2 at % relative to the entire thermoelectric material. In the case of 12 at % of ZnTe, the Zn content is 2.3 at % relative to the entire thermoelectric material.

As shown in FIG. 3 to FIG. 6, in the obtained measurement results, since the Seebeck coefficients α rarely changed even when the amounts of excess ZnTe added were increased, it was found that the carrier concentrations were approximately the same in all of the samples. On the other hand, the electric resistivity ρ and the thermal conductivity κ were minimized at y=4 at % or 6 at % when the amounts of excess ZnTe added were increased. The figures of merit Z, which are a function of the Seebeck coefficient α, the electric resistivity ρ and the thermal conductivity κ, were maximized when y=4 at %.

The Seebeck coefficient α, the electric resistivity ρ and the thermal conductivity κ are all the function of the carrier concentration, but the electric resistivity ρ and the thermal conductivity κ in Bi—Te-based thermoelectric materials significantly change depending on the orientation of crystals or a scattering source, and thus it is difficult to recognize a main factor of a change unless the carrier concentration is made to be the same. On the other hand, the absolute value of the Seebeck coefficient α is affected by the orientation of crystals or a scattering source only to a small extent and exhibits approximately almost the same value as long as the carrier concentration is the same.

Regarding the results of FIG. 3 to FIG. 6, in order to more strictly exclude the influence of the carrier concentration, the above-described characteristics of the samples were compared as described below using the weighted mobility μ_{w} represented by the following formula (1) and the lattice thermal conductivity κₗₐₜ represented by the following formula (2) and formula (3). In the following formula (1), h is the Planck constant, σ is the conductivity, e is the elementary charge, mₑ is the mass of an electron, kg is the Boltzmann constant, Tis the absolute temperature and a is the Seebeck coefficient. In the following formula (2) and formula (3), Kel is the electron thermal conductivity, Lis the Lorentz number, T is the absolute temperature and σ is the conductivity. These values are each a value corresponding to the mobility excluding the influence of the carrier concentration, the thermal conductivity excluding thermal conduction by carriers.

$${u}_{w} = \frac{3 {h}^{3} σ}{8 π {e ( 2 {m}_{e} {k}_{B} T )}^{3 / 2}} [ \frac{exp [ \frac{\vert α \vert}{{k}_{B} / e} - 2 ]}{1 + exp [ - 5 ( \frac{\vert α \vert}{{k}_{B} / e} - 1 ) ]} + \frac{\frac{3}{{π}^{2}} \frac{\vert α \vert}{{k}_{B} / e}}{1 + exp [ 5 ( \frac{\vert α \vert}{{k}_{B} / e} - 1 ) ]} ] \qquad ( 1 )$$

$${κ}_{lat} = κ - {κ}_{el} \qquad ( 2 )$$

$${κ}_{el} = LT σ \qquad ( 3 )$$

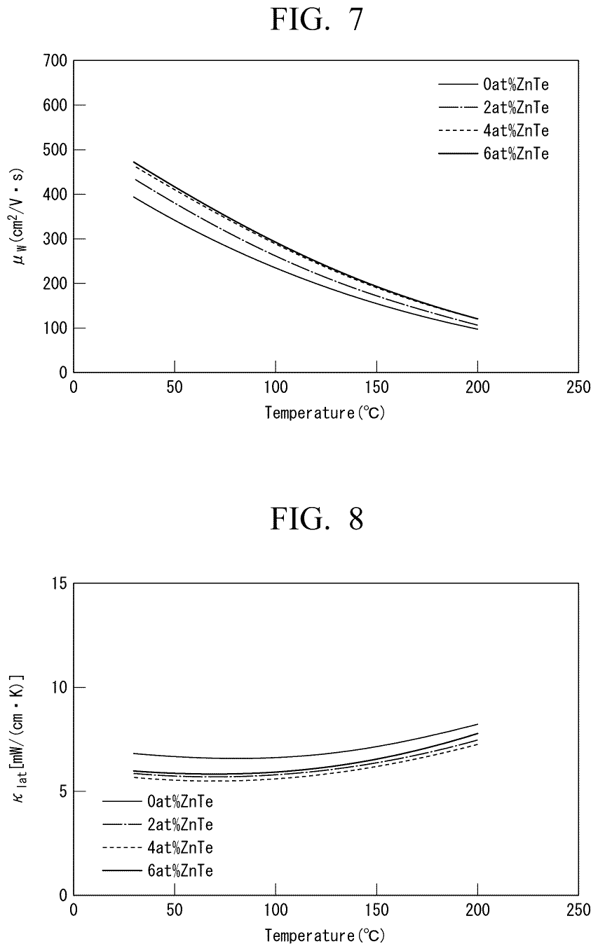

The temperature dependence of the weighted mobility μ_{w} is shown in FIG. 7. The horizontal axis of FIG. 7 indicates the temperature (° C.), and the vertical axis indicates μ_{w} (cm²/(V·s)). The temperature dependence of the lattice thermal conductivity κₗₐₜ is shown in FIG. 8. The horizontal axis of FIG. 8 indicates the temperature (° C.), and the vertical axis indicates κₗₐₜ (mW/(cm·K)). Similar to the results of FIG. 3 to FIG. 6, μ_{w} was maximized when y=6 at %, and κₗₐₜ was minimized when y=4. Both characteristics became favorable when Te and Zn, which is the element of group C, were excessively added compared with when y=0.

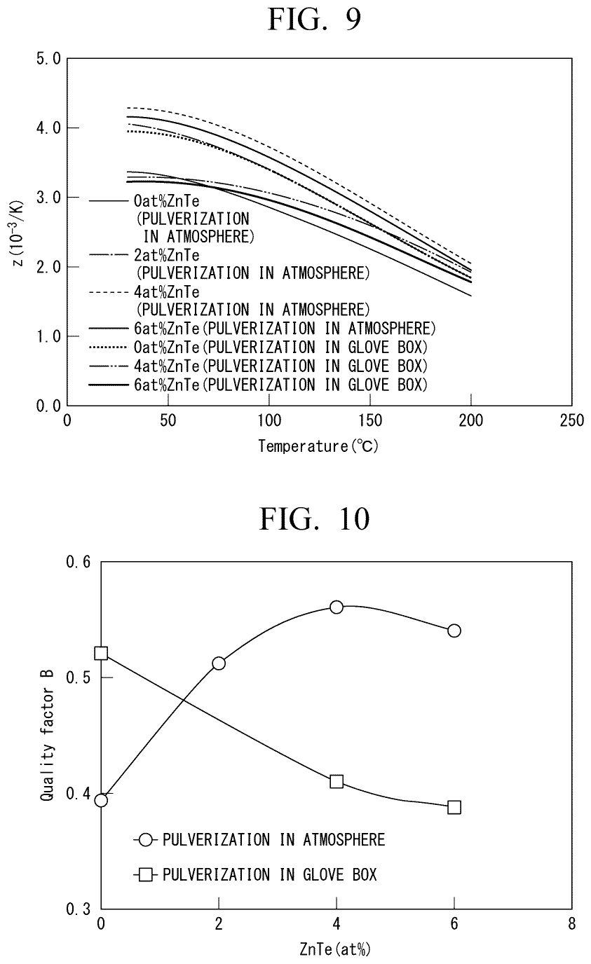

Next, a case where the p-type thermoelectric material was produced by pulverizing and powdering the ingot in the atmosphere and a case where the p-type thermoelectric material was produced by pulverizing and powdering the ingot in an inert gas atmosphere were compared. FIG. 9 shows the temperature dependence of the figures of merit Z of the p-type thermoelectric materials in the case where the ingots had been powdered in the atmosphere and the p-type thermoelectric materials in the case where the ingots had been powdered in the inert gas atmosphere (in a glove box). The horizontal axis of FIG. 9 indicates the temperature (° C.), and the vertical axis indicates the figure of merit Z (10⁻³/κ). In addition, FIG. 10 shows the temperature dependence of the quality factors B of the p-type thermoelectric material produced by powdering the ingot in the atmosphere and the p-type thermoelectric material produced by powdering the ingot in the inert gas atmosphere (in the glove box). The horizontal axis of FIG. 10 indicates the amount of ZnTe added (at %), and the vertical axis indicates the quality factor B. The quality factor B is represented by the following formula (4). In the following formula (4), h is the Planck constant, e is the elementary charge, mₑ is the mass of an electron, k_{B} is the Boltzmann constant, T is the absolute temperature, μ_{w} is the weighted mobility and κₗₐₜ is the lattice thermal conductivity.

$$B = {( \frac{{k}_{B}}{e} )}^{2} \frac{8 π {e ( 2 {m}_{e} {k}_{B} T )}^{3 / 2}}{3 {h}^{3}} \cdot \frac{{μ}_{W}}{{κ}_{lat}} T \qquad ( 4 )$$

As shown in FIG. 9, the figures of merit of the thermoelectric materials were higher in a case where the ingot was pulverized and powdered in the atmosphere than in a case where the ingot was pulverized in the inert gas atmosphere. As shown in FIG. 10, while the quality factors B were maximized at a ZnTe concentration of 4 at % in a case where the ingot was pulverized in the atmosphere, the quality factor B decreased as ZnTe increased in the inert gas atmosphere. From these results, it was found that the figure of merit can be further improved when ZnTe is added and oxygen is introduced. As a result of measuring the oxygen concentration of a thermoelectric material manufactured under the same conditions as for these samples (no Zn added, y=0 at %), the oxygen concentration was 431 ppm in a case where the ingot was pulverized in the glove box and was 1150 ppm in a case where the ingot was pulverized in the atmosphere. The oxygen concentration is assumed to be approximately the same as well in a case where ZnTe is added.

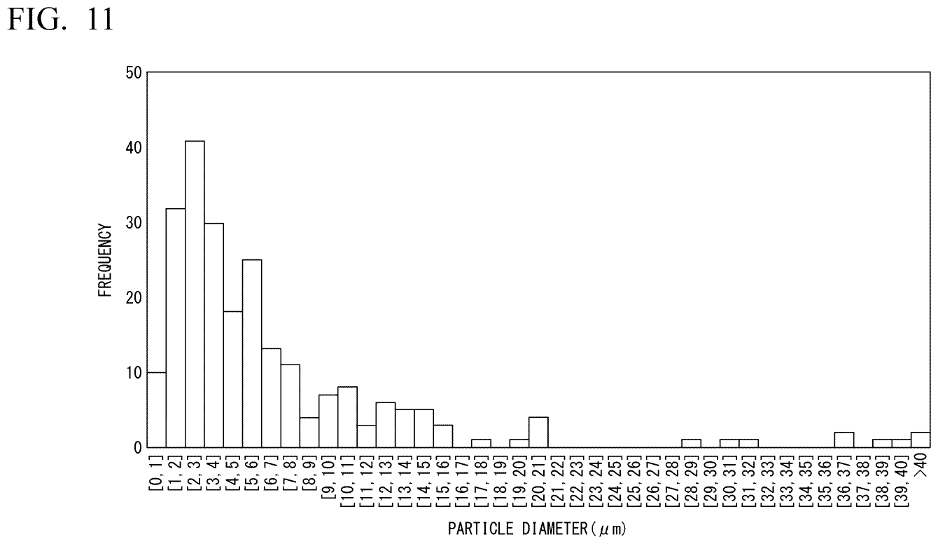

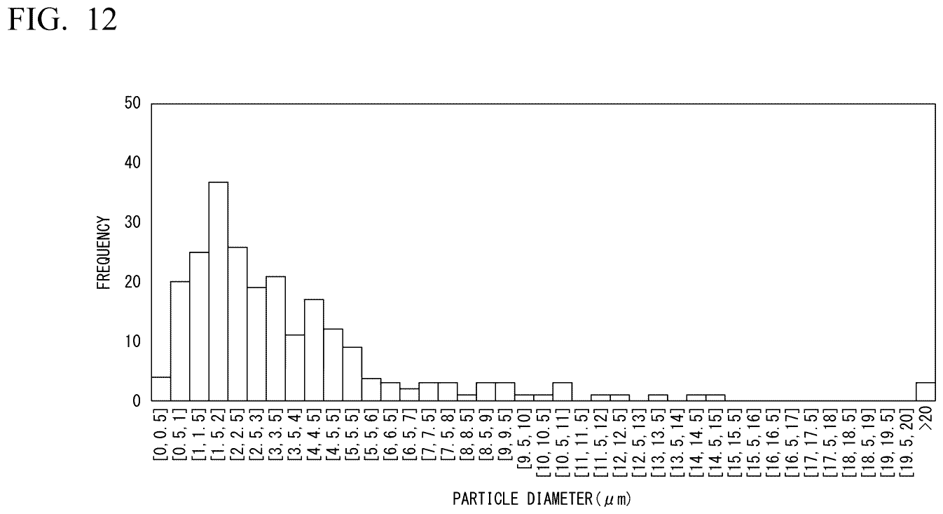

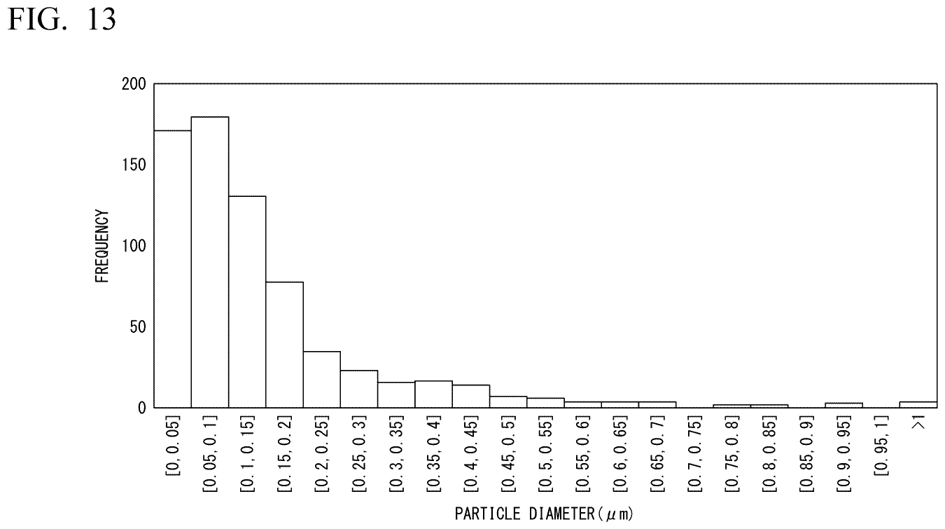

Next, the observation results of the crystal structures will be described. As a result of observing the p-type sample to which Zn and Te were excessively added (6 at %) with SEM, it was confirmed that the particles of segregated zine telluride (ZnTe) having major axes of 0.4 to 40 μm and minor axes of 0.4 to 20 μm were precipitated in at least one of the crystal grains of the matrix and the crystal grain boundaries of the matrix. The distribution of the major axes and the distribution of the minor axes of the zinc telluride particles obtained with SEM and EDS are shown in FIG. 11 and FIG. 12. FIG. 11 shows the distribution of the major axes of the zinc telluride particles. The horizontal axis of FIG. 11 indicates the particle diameter (μm), and the vertical axis indicates the frequency (number). FIG. 12 shows the distribution of the minor axes of the zinc telluride particles. The horizontal axis of FIG. 12 indicates the particle diameter (μm), and the vertical axis indicates the frequency (number). As shown in FIG. 11 and FIG. 12. 90% or more of particles of the telluride particles had major axes of 0.4 to 40 μm and minor axes of 0.4 to 20 μm.

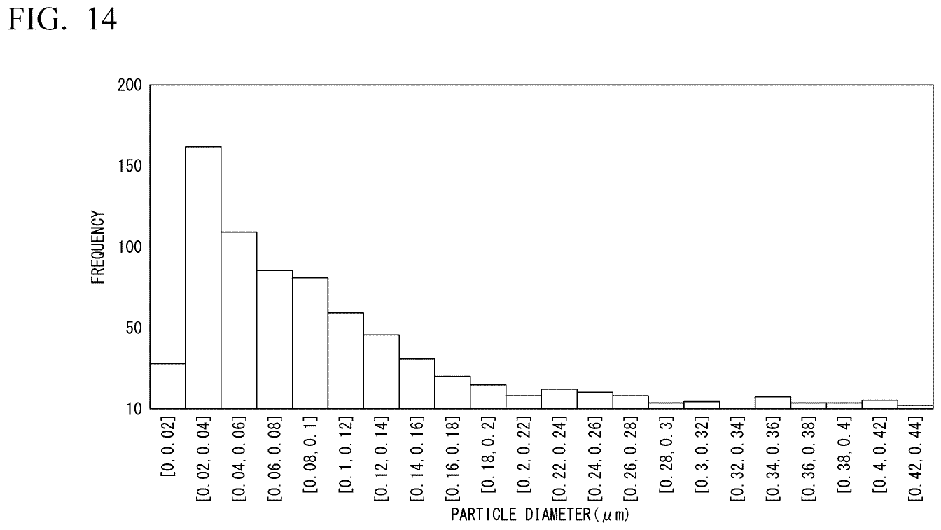

From the thermoelectric material from which the zinc telluride was observed, the major axes and minor axes of zinc oxide particles were measured with STEM-EDS. The zinc oxide particles were precipitated in at least one of the crystal grains of the matrix and the crystal grain boundaries of the matrix. The obtained results are shown in FIG. 13 and FIG. 14. FIG. 13 shows the distribution of the major axes of the zinc oxide particles. The horizontal axis of FIG. 13 indicates the particle diameter (μm), and the vertical axis of FIG. 13 indicates the frequency (number). FIG. 14 shows the distribution of the minor axes of the zinc oxide particles. The horizontal axis of FIG. 14 indicates the particle diameter (μm), and the vertical axis indicates the frequency (number). [x, y] along the horizontal axes of FIG. 13 and FIG. 4 indicates more than x and y or less. 90% or more of the zinc oxide particles had major axes of 1 nm to 1000 nm and minor axes of 1 nm to 500 nm. While it was possible to confirm a lot of zinc oxide, no Sb oxide particles were confirmed (number density: 0 particles/mm²). In addition, there were no particles of pure Zn, and the number of the zinc oxide particles was large.

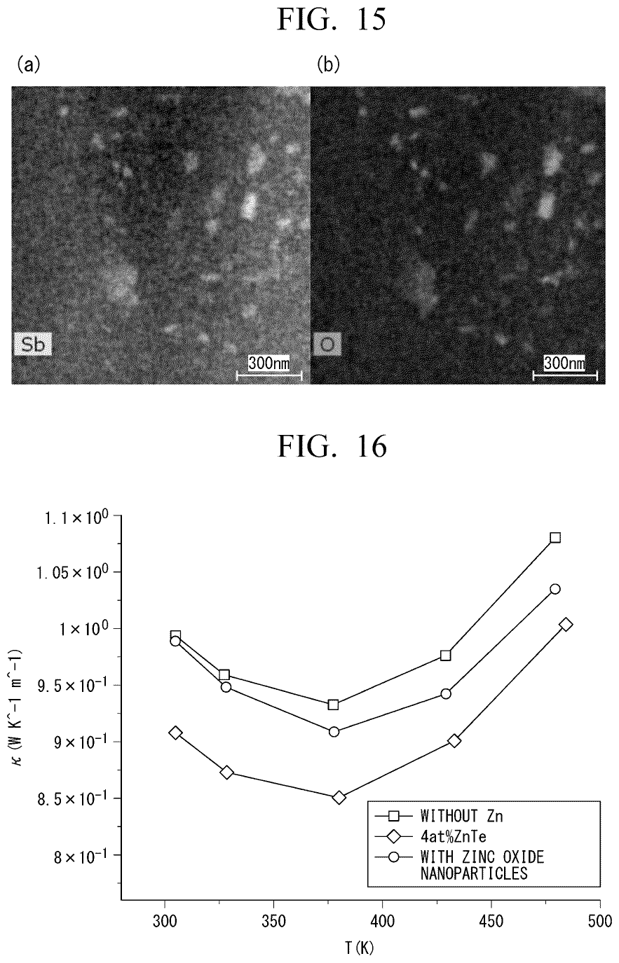

A result of the element mapping of Sb in a case where Zn was not added is shown in FIG. 15(a), and a result of the element mapping of O is shown in FIG. 15(b). In the thermoelectric material to which Zn was not added, a lot of the Sb oxide particles were observed as shown in FIG. 15. From this fact, it was confirmed that addition of pure zinc makes it possible to reduce the number of the Sb oxide particles in p-type Bi—Te-based thermoelectric materials.

FIG. 16 shows the temperature dependence of the thermal conductivity of the p-type thermoelectric material obtained by adding zinc oxide to the raw material and the p-type thermoelectric material obtained by adding pure zinc to the raw material. The horizontal axis of FIG. 16 indicates the absolute temperature (K), and the vertical axis indicates the thermal conductivity κ (WK⁻¹ m⁻¹). As shown in FIG. 16, in a case where zinc oxide was added to the raw material, the thermal conductivity was rarely reduced. On the other hand, in a case where pure zine was added to the raw material, the thermal conductivity was reduced, and the number density of the Sb oxide particles was 0 particles/mm². Similarly, the number density of the Bi oxide particles was also 0 particles/mm². In addition, in a case where zinc was added in a zinc oxide state, zinc was not fused, and the distribution of the zinc oxide particles were outside the scope of the present invention. From this fact, it was confirmed that, when pure zinc is added to the raw material and the raw material is melted and solidified, the performance of a thermoelectric material can be improved.

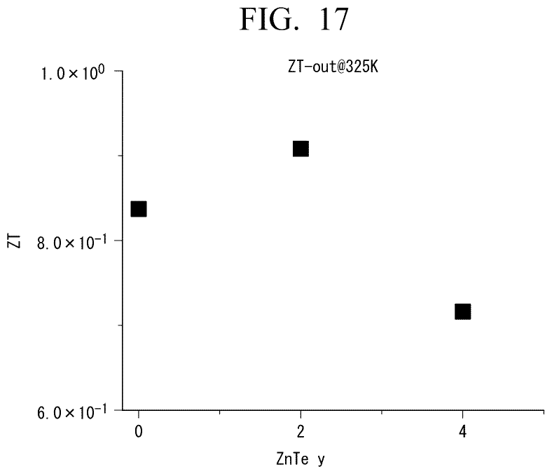

FIG. 17 is a view showing the ZnTe amount dependence of the dimensionless figure of merit ZT of the n-type thermoelectric material 2 at near room temperature (325 K). The horizontal axis of FIG. 17 indicates the ZnTe amount (at %), and the vertical axis indicates the dimensionless figure of merit ZT. As shown in FIG. 17, when y=2, the dimensionless figure of merit became higher than that when ZnTe was not added (y=0%).

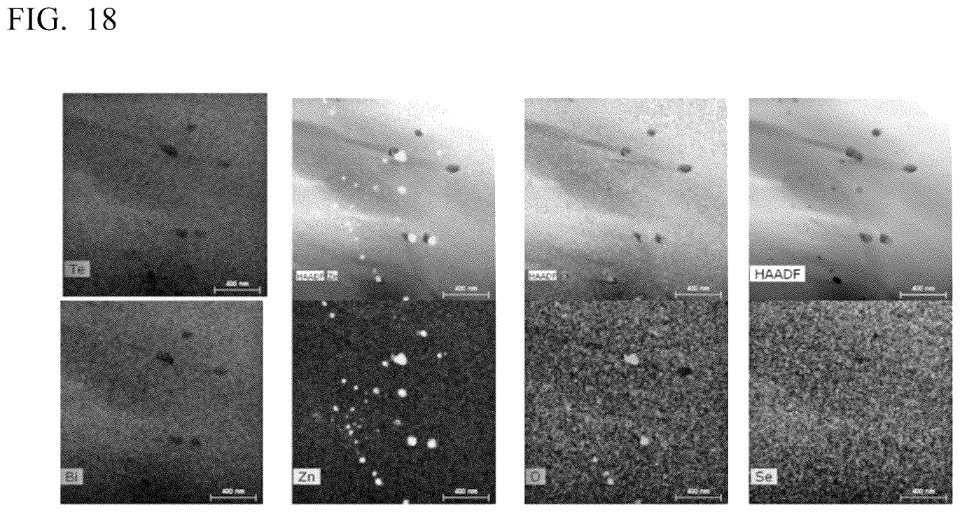

FIG. 18 shows the element mapping results of the n-type thermoelectric material 2. As shown in FIG. 18, since Zn and O were detected in the particles that were confirmed, it was confirmed that a large number of the nanoparticles of zinc oxide were present.

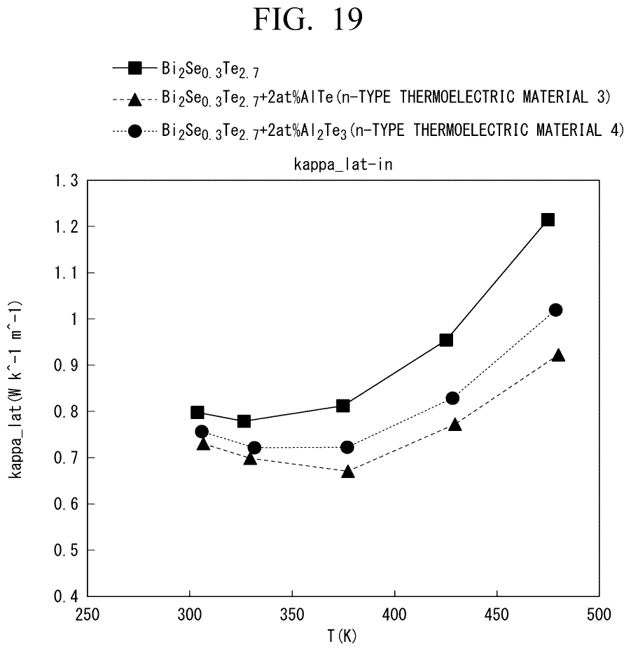

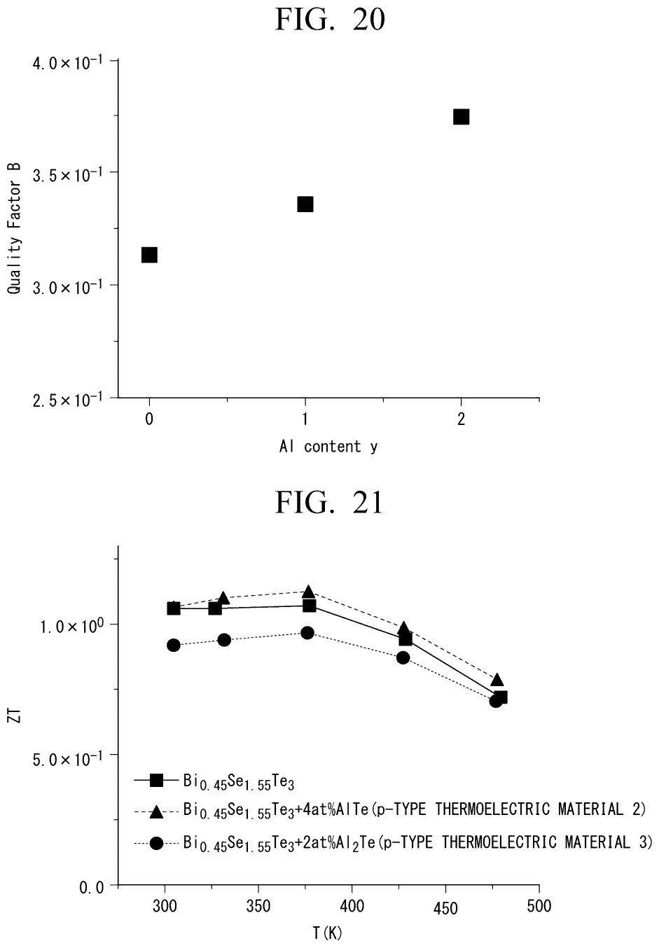

FIG. 19 shows the temperature dependence of the lattice thermal conductivities κₗₐₜ of Bi₂Se_{0.3}Te_{2.7}, the n-type thermoelectric material 3 and the n-type thermoelectric material 4. The horizontal axis of FIG. 19 indicates the temperature (° C.), and the vertical axis of FIG. 19 indicates the thermal conductivity κ (mW/(cm·K)). In Al-added samples, there was a tendency that the lattice thermal conductivities were low compared with those of Al-free samples. For these samples, the Seebeck coefficient, the electric resistivity and the thermal conductivity, which are the functions of the carrier concentration, also each significantly varied, Quality factor B, which is indicator of performance that is not affected by the carrier concentration, was calculated. FIG. 20 shows the relationship between Quality factor B and the Al amount. In FIG. 20, y=1 indicates the result of the n-type thermoelectric material 4, and y=2 indicates the result of the n-type thermoelectric material 3. In the Al-added samples, the values of Quality factor were above those of the Al-free samples in the samples of y=1 and y=2 particularly in a direction vertical to the sintering direction.

FIG. 21 shows the temperature dependence of the dimensionless figures of merit ZT of Bi_{0.45}Sb_{1.55}Te₃, the p-type thermoelectric material 2 and the p-type thermoelectric material 3. The horizontal axis of FIG. 21 indicates the temperature (K). The dimensionless figure of merit ZT of the p-type thermoelectric material 3 was larger than that of Bi_{0.45}Sb_{1.55}Te₃. From this fact, it was confirmed that, when pure Al is added to the raw material and the raw material is melted and solidified, the performance of a thermoelectric material can be improved.

### INDUSTRIAL APPLICABILITY

The thermoelectric material according to the embodiment has an excellent figure of merit and thus has excellent industrial applicability.

### REFERENCE SIGNS LIST

S1 Melting and solidification step
S2 Powder production step
S3 Sintering step

1. A thermoelectric material having a matrix in which a chemical formula is represented by A₂B₃, A in the chemical formula is one or more elements selected from the group consisting of Bi and Sb, and B in the chemical formula is one or more elements selected from the group consisting of Te, Se and S,
wherein, in at least one of crystal grains of the matrix and crystal grain boundaries of the matrix,
oxide particles containing one or more elements selected from a group C consisting of Zn, Nb and Al and
telluride particles containing one or more elements selected from the group C are precipitated,
major axes of the oxide particles are 1 nm to 1000 nm,
minor axes of the oxide particles are 1 nm to 500 nm,
major axes of the telluride particles are 0.4 μm to 40 μm, and
minor axes of the telluride particles are 0.4 μm to 20 μm.

2. The thermoelectric material according to claim 1,
wherein at least one of the oxide particles and the telluride particles contain at least Zn.

3. The thermoelectric material according to claim 1,
wherein at least one of the oxide particles and the telluride particles contain at least Nb.

4. The thermoelectric material according to claim 1,
wherein at least one of the oxide particles and the telluride particles contain at least Al.

5. The thermoelectric material according to claim 1,
wherein the number of the oxide particles is larger than the number of the telluride particles.

6. The thermoelectric material according to claim 1,
wherein a maximum value of number densities of Sb oxide particles is 31.2 particles/μm² or less.

7. The thermoelectric material according to claim 1,
wherein a maximum value of number densities of Bi oxide particles is 12.4 particles/mm² or less.

8. The thermoelectric material according to claim 1,
wherein an oxygen concentration is 100 ppm or more, and the number of the oxide particles is larger than the number of particles of a pure element of the group C.

9. The thermoelectric material according to claim 1,
wherein an oxygen concentration is 400 ppm or more, and the number of the oxide particles is larger than the number of particles of a pure element of the group C.

10. The thermoelectric material according to claim 1,
wherein an oxygen concentration is 1000 ppm or more, and the number of the oxide particles is larger than the number of particles of a pure element of the group C.

11. The thermoelectric material according to claim 1,
wherein a Zn content is 0.40 to 2.4 at %.

12. The thermoelectric material according to claim 1,
wherein an Al content is 1.99 to 3.97 at %.

13. A thermoelectric element,
wherein the thermoelectric material according to claim 1 is used.

14. A thermoelectric module,
wherein the thermoelectric element according to claim 13 is used.

15. A device,
wherein the thermoelectric module according to claim 14 is used.

16. A method for manufacturing the thermoelectric material according to claim 1, comprising:
a melting and solidification step of melting and solidifying a raw material containing at least one element selected from the group A consisting of Bi and Sb,
at least one element selected from the group B consisting of Te, Se and S and
at least one element selected from the group C consisting of Zn, Nb and Al to obtain a solidified product;
a powder production step of obtaining a powder from the solidified product; and
a sintering step of sintering the powder,
wherein at least some of the element selected from the group C in the raw material is present as a pure element.

17. The method for manufacturing the thermoelectric material according to claim 16,
wherein, in the powder production step, the solidified product is pulverized in the atmosphere.

18. The thermoelectric material according to claim 2,
wherein the number of the oxide particles is larger than the number of the telluride particles.

19. The thermoelectric material according to claim 2,
wherein a maximum value of number densities of Sb oxide particles is 31.2 particles/μm² or less.

20. The thermoelectric material according to claim 2,
wherein a maximum value of number densities of Bi oxide particles is 12.4 particles/mm² or less.
